(19) United States
(12) Patent Application Publication
(10) Pub. No.: US 2020/0408633 A1
(43) Pub. Date: Dec. 31, 2020

(54) SYSTEMS AND METHODS FOR MEASURING STRUCTURAL ELEMENT DEFLECTIONS

(71) Applicant: MachineSense, LLC, Baltimore, MD (US)

(72) Inventors: Biplab Pal, Ellicott City, MD (US); Joy Bagchi, Thakurnagar (IN); Antara Ain, Howrah (IN); Conrad Bessemer, Millersville, MD (US)

(73) Assignee: MachineSense, LLC, Baltimore, MD (US)

(21) Appl. No.: 16/715,116

(22) Filed: Dec. 16, 2019

Related U.S. Application Data
(60) Provisional application No. 62/866,299, filed on Jun. 25, 2019.

(51) Int. Cl. G01M 5/00

(52) U.S. Cl. CPC G01M 5/0033; G01R 1/16; G01M 5/0091

(57) ABSTRACT

Systems and methods for monitoring the condition of structural systems such as bridges and roadbeds. The systems include a magnetometer mounted on a structural element of the structural system; and a magnet mounted on a surface adjacent the structural element so that the magnetometer is positioned within a magnetic field of the magnet. The magnetometer measures characteristics of the magnetic field of the magnet. Position of the structural element is determined from measured characteristics of the magnetic field and a predetermined relationship between the characteristics of the magnetic field and the position of the structural element within the magnetic field. The position information determines other parameters, such as the deflection of the structural element in three-dimensional space, and the response of the structural element to dynamic loading.

### CROSS REFERENCE TO RELATED PATENT APPLICATIONS

This patent application claims the benefit of the filing date of U.S. provisional patent application 62/866,299, entitled “Dynamic Measurement of 3 Axis Deflection for Structural Heath Monitoring Using a Magnet and Magnetometer,” filed 25 Jun. 2019, the contents of which are incorporated by reference herein in their entirety; priority is claimed under 35 USC § 120.

### STATEMENT REGARDING FEDERALLY SPONSORED RESEARCH OR DEVELOPMENT

Not applicable—this invention was conceived and developed entirely using private source funding; this patent application is being filed and paid for entirely by private source funding.

### DESCRIPTION OF THE PRIOR ART

Structural health monitoring involves monitoring the condition of structural systems such as bridges, roadbeds, flyovers, dams, skyscrapers, etc. Condition monitoring is the process of monitoring certain parameters of a system for significant variations that can indicate a need for some type of action, such as an alarm or maintenance notification. When applied to structural systems, condition monitoring can facilitate implementation of maintenance and other actions that reduce the potential for structural degradation and failure, and eliminate monetary costs and dangers that can result therefrom.

Condition monitoring of structures and structural systems typically includes monitoring vibrational signature of individual structural elements using, for example, accelerometers; signatures resulting from laser scanning and signatures resulting from radio-frequency identification. Measuring three-axis, i.e., three-dimensional, deflection of structural elements is important when assessing the health of a structure. Such deflection can occur when a dynamic load is applied to the structure, such as when a truck drives across a bridge. Measurement of the maximum deflection of structural elements, and the dynamic response of the structure retraction from the deflection are critical, and are of prime importance when monitoring structural integrity.

Structural health monitoring is gaining in importance because it can improve human safety and reduce maintenance costs. One of the challenges in structural health monitoring, however, is in performing the requisite analyses, and generating actionable information in real-time. This challenge exists due, in general, to the absence of infrastructure facilities capable of providing the requisite data analyses; the costs of conducting calibration and empirical data gathering on-site at the structure; and the lack of on-site data-processing capabilities.

Many methods for measuring the deflection of structural members currently exist. These methods include, for example, laser scanning technology, the dial indicator method, and the total station method. Such methods, however, can be costly and have limitations. For example, the results of the total station method can be affected by temperature changes and humidity. Also, most of these methods are limited to determining single-axis axis deflection of a structural member, and many of the methods cannot be adapted to dynamic monitoring, i.e. gathering data, analyzing the data, and generating actionable information on a real-time or near real-time basis.

Many bridges can benefit from structural health monitoring due to their relative complexity, exposure to the elements, heavy traffic volume, high maintenance costs, etc. Structural deflection can be monitored at many locations on a bridge, such as at mid-span, girder joints, beam joints, and concrete joints. For example, FIGS. 1, 2, and 13 through 16 schematically depict a bridge 100. The bridge 100 includes two or more girders 102. Each girder 102 is a large, horizontally-oriented beam, or a compound structure, that is mounted on preferably concrete piers 108 partially embedded in the ground. The girder 102 spans the space between two or more of the piers 108, and in combination with one or more other girders 102 supports a road deck 110 of bridge 100. An upper surface of road deck 110 provides a roadway for vehicular traffic crossing bridge 100.

FIG. 13 depicts a girder 102 of bridge 100 experiencing maximum deflection at mid-span in response to vehicular traffic on road deck 110. As can be seen in FIG. 13, this deflection occurs primarily in one direction, namely vertically. Thus, when monitoring the health of the bridge at mid-span, measurement of vertical deflection alone usually is sufficient.

At other locations on the bridge, however, the presence of faults may result in horizontal structural deflection, as well as vertical structural deflection. Horizontal deflection is more prominent during active/dynamic loading conditions than during static loading, due primarily to the action and reaction forces produced by a dynamic load, as can be seen in the side view of the bridge in FIG. 14, and the top view in FIG. 15.

Also, if a joint is located at or near a curved portion of the bridge roadway, the centrifugal force generated by the moving vehicles can cause structural deflection in three axes. Vertical deflection is due primarily to load exerted by the vehicle; while deflection along the two horizontal axes is primarily due to centrifugal forces, as shown in FIG. 16.

Thus, measuring structural deflection in three dimensions can be critical to conducting effective structural health monitoring of bridges and other structures.

### SUMMARY OF THE INVENTION

The present disclosure relates generally to systems and methods for monitoring the health of structural systems by determining the deflection of individual structural members of the structural systems using a magnet and a magnetometer.

In the literature magnetic forces are usually described as being magnetic fields in which the magnetic forces are characterized as vector quantities. Magnetic force is measured in gauss. Gauss is expressed in units of “centimeter-gram-seconds”.

In this patent application the terms “sensor” and “magnetometer” are used largely interchangeably, as is clear from their context. “Sensor” is to be understood as a device for measuring gauss in centimeter-gram-seconds and providing a signal, in digital form, indicative of the measured value of gauss. “Magnetometer” is similarly to be understood as a device for measuring gauss in centimeter-gram-seconds and providing a signal in digital form, indicative of the measured value of gauss. The preferred “sensor” and “magnetometer” as addressed in this application provide digital signals of the value of gauss measured in three different directions simultaneously, with the directions corresponding to a conventional orthogonal x, y, z coordinate system. Sometimes herein the magnetometer is referred to as a “tri-axial” magnetometer, meaning that the digital signal provided by the magnetometer (or the “sensor” if the context indicates) has three components, one each indicating the measured value of gauss along each of the x, y, z axes of a conventional orthogonal x, y, z coordinate system.

Occasionally herein there is discussion of calibrating or otherwise using the magnetometer (or “sensor”) with respect to just the x and y axes, i.e. in a two dimensional application. From context it will be understood that in such cases, a “tri-axial” magnetometer may be used with the output signal for gauss measured in the “z” direction being ignored. In other instances and essentially throughout the application from context it will be understood that “magnetometer” and “sensor” denote devices measuring gauss in centimeter-gram-seconds and providing digital signals indicative of the measured values of gauss in three directions corresponding to a conventional orthogonal x, y, z coordinate system. These tri-axial magnetometers are preferably configured to furnish output digital signals wirelessly to some other output device, using one or more of the communication protocols noted herein.

In accordance with various aspects of the inventive concepts disclosed herein, systems for monitoring a structural element include a magnetometer capable of being mounted on the structural element, and a magnet capable of being mounted on a surface adjacent the structural element so that the magnetometer is positioned within the magnetic field of the magnet. The systems also include a computing device capable of being communicatively coupled to the magnetometer. The magnetometer is configured to measure characteristics of the magnetic field of the magnet. The computing device is configured to determine position of the magnetometer in relation to the magnet based on the measured characteristics of the magnetic field.

In another aspect of this invention, the computing device is configured to determine a position of the magnetometer in relation to the magnet in three-dimensional space based on measured characteristics of the magnetic field.

In another aspect of this invention, measured characteristics of the magnetic field include magnitude of the magnetic field in three orthogonal directions.

In another aspect of this invention, the systems also include a gateway communicatively coupled to the magnetometer and configured to transmit output of the magnetometer to the computing device over the Internet.

In another aspect of the invention, the computing device includes a memory containing information regarding a relationship between the characteristics of the magnetic field and the position of the magnetometer in relation to the magnet.

In another aspect of the invention, the computing device is further configured to determine deflection of the structural member by calculating difference between the position of the structural member in relation to the magnet at a first time, and position of the structural member in relation to the magnet at a second time.

In another aspect of the invention, the computing device is further configured to determine a dynamic response of retraction of the structural member from a deflection position.

In another aspect of the invention, the magnetometer is a three-axis magnetometer and the computing device is further configured to determine a deflection of the structural member by calculating a difference between the position of the structural member in relation to a first reference axis and the magnet at a first time, and the position of the structural member in relation to the first reference axis and the magnet at a second time; difference between the position of the structural member in relation to a second reference axis and the magnet at the first time, and the position of the structural member in relation to the second reference axis and the magnet at the second time; and difference between position of the structural member in relation to a third reference axis and the magnet at the first time, and position of the structural member in relation to the third reference axis and the magnet at the second time, with the first, second and third reference axes being orthogonal.

In another aspect of the invention, the computing device is further configured to continually monitor the position of the magnetometer in relation to the magnet.

In another aspect of the invention, the computing device is further configured to generate a visible, audible and/or electronic notification when the deflection of the structural member exceeds a predetermined value.

In another aspect of the invention, the structural element is part of a structure having a roadway; and the system further includes a load measuring device configured to be communicatively coupled to the computing device, and to determine a load on the roadway.

In another aspect of the invention, the computing device is further configured to determine a maximum load on the roadway by determining the load on the roadway when the deflection of the structural member reaches a predetermined limit.

In another aspect of the invention, the computing device is a first computing device, and the system further includes a second computing device configured to be communicatively coupled to the first computing device, and further configured to store data relating to the measured characteristics of the magnetic field and/or to perform additional processing operations on the data relating to the measured characteristics of the magnetic field.

In another aspect of the invention, the surface adjacent the structural element is a surface that does not deflect substantially when the structural element is subjected to a load within the structural limitations of the structural element.

In another aspect of the invention, the computer-executable instructions are further configured to determine a deflection of the structural member when the structural member is subjected to a structural load by calculating a difference between position of the magnetometer in relation to the magnet when the structural member is not subjected to the structural load, and position of the magnetometer in relation to the magnet when the structural member is subjected to the structural load.

In another aspect of the invention, methods for monitoring structural elements include mounting a magnetometer on the structural element, and mounting a magnet on a surface adjacent the structural element so that the magnetometer is positioned within a magnetic field of the magnet. The methods further include measuring characteristics of the magnetic field of the magnet using the magnetometer, and determining a position of the magnetometer in relation to the magnet based on the measured characteristics of the magnetic field.

In another aspect of the invention, measuring characteristics of the magnetic field of the magnet includes measuring characteristics of the magnetic field in three orthogonal directions.

In another aspect of the invention, measuring characteristics of the magnetic field of the magnet includes measuring a strength of the magnetic field.

In another aspect of the invention, determining a position of the magnetometer in relation to the magnet based on the measured characteristics of the magnetic field includes determining the position of the magnetometer in relation to the magnet based on a relationship between the characteristics of the magnetic field, and the position of the magnetometer in relation to the magnet.

In another aspect of the invention, mounting a magnet on a surface adjacent the structural element so that the magnetometer is positioned within a magnetic field of the magnet includes mounting the magnet on a surface that does not deflect substantially when the structural element is subjected to a load within the structural limitations of the structural element.

In another aspect of the invention, the methods further include determining a deflection of the structural member by calculating a difference between a position of the structural member in relation to the magnet at a first time, and a position of the structural member in relation to the magnet at a second time.

In another aspect of the invention, the methods further include determining a deflection of the structural member when the structural member is subjected to a structural load by calculating a difference between a position of the magnetometer in relation to the magnet when the structural member is not subjected to the structural load, and a position of the magnetometer in relation to the magnet when the structural member is subjected to the structural load.

In another aspect of the invention, the methods further include determining a maximum load on a roadway supported at least in part by the structural member by measuring loads on the roadway and identifying the load on the roadway when the deflection of the structural member reaches a predetermined maximum value.

In another aspect of the invention, the methods further include determining a dynamic response of retraction from the deflection by the structural member.

In another aspect of the invention, determining a deflection of the structural member further includes calculating a difference between the position of the structural member in relation to a first reference axis and the magnet at a first time, and the position of the structural member in relation to the first reference axis and the magnet at a second time; calculating the difference between a position of the structural member in relation to a second reference axis and the magnet at the first time, and the position of the structural member in relation to the second reference axis and the magnet at the second time; and calculating a difference between the position of the structural member in relation to the third reference axis and the magnet at the second time, with the first, second and third reference axes being orthogonal.

In another aspect of the invention, the methods further include generating a notification when deflection of the structural member exceeds a predetermined limit.

In another aspect of the invention, the methods further include determining the relationship between the characteristics of the magnetic field, and the position of the magnetometer in relation to the magnet by placing the magnetometer in a first position in relation to the magnet, measuring the first position of the magnetometer in relation to the magnet, determining the response of the magnetometer to the magnetic field at the first position, correlating the measured first position of the magnetometer to the response of the magnetometer to the magnetic field at the first position, placing the magnetometer in a second position in relation to the magnet, measuring the second position of the magnetometer in relation to the magnet, determining the response of the magnetometer to the magnetic field at the second position, and correlating the measured second position of the magnetometer to the response of the magnetometer to the magnetic field at the second position.

In another aspect of the invention, determining the relationship between the characteristics of the magnetic field, and the position of the magnetometer in relation to the magnet further includes using neural networking to predict a response of the magnetometer to the magnetic field at a third position in relation to the magnet, based on the responses of the magnetometer to the magnetic field at the first and second positions.

In another aspect of the invention, the magnetometer is a first magnetometer, and the methods further include removing the first magnetometer from the structural element, mounting a second magnetometer on the structural element, measuring characteristics of the magnetic field of the magnet using the second magnetometer, measuring the position of the second magnetometer in relation to the magnet, determining, from the relationship between the characteristics of the magnetic field and the position of the first magnetometer in relation to the magnet, a response of the first magnetometer to the magnetic field of the magnet at the measured position of the second magnetometer, determining a difference between the response of the first magnetometer to the magnetic field of the magnet at the measured position of the second magnetometer, and the response of the second magnetometer to the magnetic field of the magnet at the measured position of the second magnetometer, based on the difference, adjusting the relationship between the characteristics of the magnetic field and the position of the first magnetometer in relation to the magnet, and determining the position of the second magnetometer in relation to the magnet based on the adjusted relationship between the characteristics of the magnetic field, and the position of the first magnetometer in relation to the magnet.

In another aspect of the invention, systems for monitoring a structural element include a magnet capable of being mounted on the structural element, and a magnetometer capable of being mounted on a surface adjacent the structural element so that the magnetometer is positioned within the magnetic field of the magnet. The systems also include a computing device capable of being communicatively coupled to the magnetometer. The magnetometer is configured to measure characteristics of the magnetic field of the magnet. The computing device is configured to determine position of the magnetometer in relation to the magnet based on the measured characteristics of the magnetic field.

In another aspect of the invention, methods for monitoring structural elements include mounting a magnet on the structural element, and mounting a magnetometer on a surface adjacent to the structural element so that the magnetometer is positioned within a magnetic field of the magnet. The methods further include measuring characteristics of the magnetic field of the magnet using the magnetometer, and determining a position of the magnetometer in relation to the magnet based on the measured characteristics of the magnetic field.

In another one of its aspects, this invention provides a method for measuring structural deflection which begins by positioning a wireless magnetometer on a portion of the structure where deflection is to be measured. The method proceeds by fixedly positioning a magnet within wireless communication range of the magnetometer and sufficiently close to the structural portion of interest that the structural portion of interest is within the magnetic field of the magnet. The method then proceeds by sensing a magnetic field vector with the magnetometer as the portion of the structure deflects. The method then dynamically provides the sensed magnetic field position vector to an edge cloud computing device as the portion of the structure has deflected. The method then further proceeds by extracting, as deflection information, the position of the portion of the structure for which deflection is being measured from the dynamically provided magnetic field vector position; this is performed by an algorithm executed by the edge cloud computing device. The method concludes with wirelessly transmitting the deflection information from the edge cloud computing device to a user, preferably via the internet.

In a principal method aspect of the invention, the structural deflection to be measured is vertical deflection, which is measured by positioning the magnetometer and the magnet in vertical alignment, one with another, preferably with the magnet below the magnetometer.

In yet another one of its aspects, this invention provides a method for calibrating a sensing magnetometer to be used in conjunction with a magnet for detecting structural deflection. The calibration method proceeds by moving a reference magnetometer through a pre-selected space to collect data of magnetic field strength of the magnet respecting a three-axis coordinate system. The magnet is then positioned such that the magnetic field thereof no longer occupies the pre-selected space. The method yet further proceeds by moving the reference magnetometer through the pre-selected space to collect data of the earth's magnetic field respecting the three-axis coordinate system. Next, the method proceeds by subtracting the magnetic field data collected in the previous step from the magnetic field data collected in the step in which the magnet has been moved so that it no longer occupies the pre-selected space, resulting in production of a data set containing only magnetic field components of the magnet's magnetic field as measured by the reference magnetometer respecting the three-axis coordinate system. The method then proceeds by applying the magnetic field components resulting from the subtraction step for each of the directions defined by the coordinate system to at least one neural network to produce a machine learning training set for the three-position coordinates of the reference magnetometer relative to the magnet. The method then further proceeds by positioning a sensing magnetometer at the same selected position within the magnetic field of the magnet and measuring strength of the magnetic field thereat with the sensing magnetometer, to produce training set magnetic field strength data for the sensing magnetometer. Then the magnetic field strength sensed by the sensing magnetometer in the training set is subtracted from the magnetic field strength sensed by the reference magnetometer to determine calibration of the sensing magnetometer relative to the reference magnetometer.

In yet another one if its aspects, the invention provides a method for measuring structural deflection by providing a magnet having a magnetic field occupying a pre-selected space, moving a wireless magnetometer through the pre-selected space to collect data of magnetic field strength of the magnet respecting a three-axis coordinate system. The method then proceeds by positioning the magnet such that the magnetic field of the magnet no longer fills the pre-selected space. The method then proceeds by moving the magnetometer through the pre-selected space to collect data of just the earth's magnetic field respecting the three-axis coordinate system. The method then proceeds by subtracting the earth magnetic field data collected in the course of moving the magnetometer though the space, from the magnetic field data collected when the magnet was in the pre-selected space, to produce a data set containing only the magnetic field components of the magnet as measured by the magnetometer respecting the three-axis coordinate system, without magnetic field components supplied by the earth's magnetic field. The method concludes by applying, for each of the three directions defined by the coordinate system, the magnetic field components as found by performance of the subtraction step to neural networks to produce a machine learning for determining the three position coordinates of the magnetometer relative to the magnet.

The following description is merely exemplary in nature and is not intended to limit the described embodiments of the invention or uses of the described embodiments. As used herein, the words “exemplary” and “illustrative” mean “serving as an example, instance, or for illustration.” Any implementation or embodiment or abstract disclosed herein as being “exemplary” or “illustrative” is not to be construed as preferred or advantageous over other implementations, aspects, or embodiments. All of the implementations or embodiments described in the description are exemplary implementations and embodiments provided to enable persons of skill in the art to make and to use the implementations and embodiments as disclosed below, to otherwise practice the invention, and are not intended to limit the scope of the invention, which is defined by the claims.

Furthermore, by this disclosure, there is no intention to be limited by any express or implied theory presented in the preceding materials, including but not limited to the summary of the invention or the description of the prior art, or in the following description of the invention. It is to be understood that the specific implementations, devices, processes, aspects, and the like illustrated in the drawings and described in the following portion of the application are simply exemplary embodiments of the inventive concepts defined in the claims. Accordingly, specific dimensions and other physical characteristics relating to the embodiments disclosed herein are not to be considered as limiting as respecting the invention unless the claims or the specification expressly state otherwise.

### DESCRIPTION OF THE DRAWINGS

FIG. 1 is a schematic drawing of an apparatus for monitoring health of a girder positioned at mid-span of a bridge, using a magnetic-field tri-axial sensor.

FIG. 2 is a schematic illustration of an apparatus for monitoring health of a support bearing/dummy girder in a bridge using the magnetic-field tri-axial sensor.

FIG. 3 is a schematic block diagram of certain mechanical and electrical components used in embodiments of the apparatus illustrated in FIGS. 1 and 2.

FIG. 4 is a schematic block diagram of a computing device portion of the apparatus illustrated in FIG. 3.

FIGS. 5A and 5B collectively are a flowchart depicting use of apparatus such as shown in FIGS. 1 and 2 to conduct structural health monitoring of a structural element such as a bridge roadway or support beam.

FIG. 6 is a schematic illustration of a portion of apparatus for performing two-axis structural deflection measurement in an experimental environment.

FIG. 7 is a schematic illustration of apparatus for performing three-axis structural deflection measurement in an experimental environment.

FIG. 7A schematically depicts a three axis coordinate system with a wireless magnetometer at the origin and a magnet spaced therefrom on the negative z axis.

FIG. 8 is a plot of a magnetic field in an x-y plane, as measured by apparatus shown in FIG. 6.

FIG. 9 is a schematic illustration of neural networks useful in the course of practice of the invention.

FIG. 10A is a plot showing predicted and actual values of a magnetic field along the x-axis of a three axis coordinate system, as determined by a sensor.

FIG. 10B is a plot showing predicted and actual values of a magnetic field along the y-axis, as determined by the same sensor as for FIG. 10A.

FIG. 10C is a plot showing predicted and actual values of a magnetic field along the z-axis, as determined by the same sensor as for FIGS. 10A and 10B.

FIG. 11 is a plot of magnetic field data acquired from a sensor installed on a bridge carrying traffic.

FIG. 12 is a plot of structural element position data generated from the magnetic field data shown in FIG. 11.

FIG. 13 is a schematic illustration of vertical deflection of a bridge roadway support girder in response to vertical loading.

FIG. 14 is a schematic side view of a bridge carrying a car.

FIG. 15 is a schematic top view of deflection of the bridge of FIG. 14, where the deflection is transverse to direction of travel of the car.

FIG. 16 is a schematic illustration of deflection of the bridge of FIG. 14, where the deflection is tangential to direction of travel of the car.

### DESCRIPTION OF THE INVENTION

The inventive concepts are described with reference to the attached figures. The figures are not drawn to scale but do illustrate the inventive concepts. The figures do not limit the scope of the disclosure.

Several aspects of the inventive concepts embodied in the invention are described below with reference to exemplary applications for illustration. Numerous specific details, relationships, and methods are set forth to provide a full understanding of the inventive concepts. One having skill in the relevant art, however, will readily recognize that the inventive concepts can be practiced without one or more of the specific details or with other methods. In other instances, well-known structures or operations are not shown in detail, to avoid obscuring the inventive concepts.

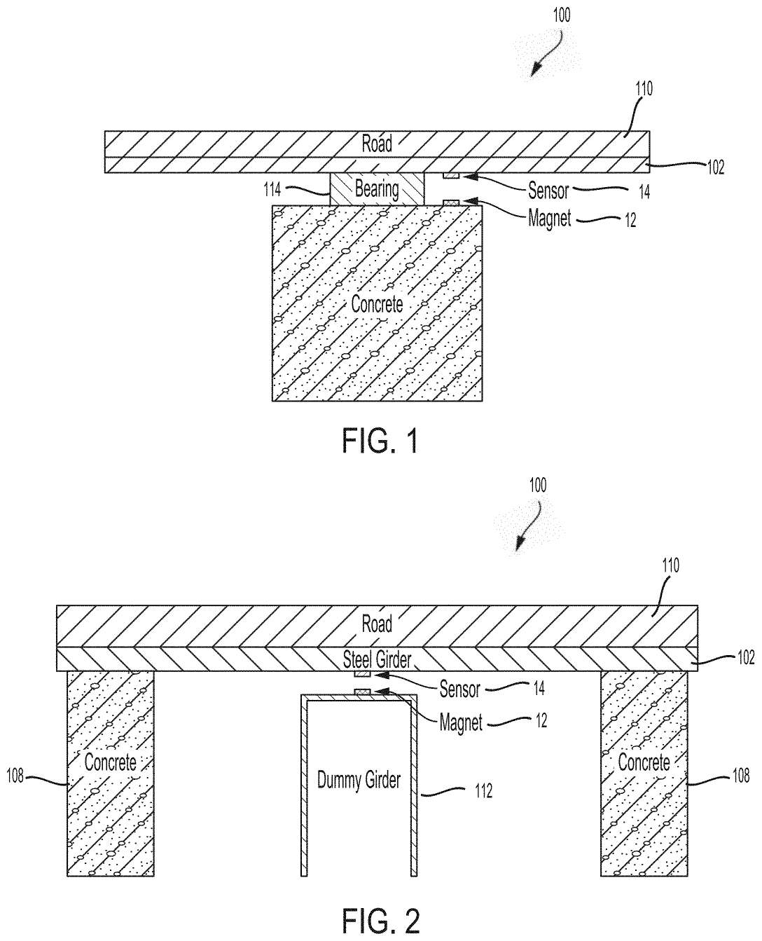

Systems and methods are provided for determining the deflection of structural elements. The structural elements can be components of bridge 100 depicted in FIGS. 1, 2, and 13 through 16. This particular application is disclosed for illustrative purposes only; the inventive concepts can be applied to other types of structures.

FIG. 1 depicts an embodiment of the invention in the form of a system. The system comprises a magnet 12, and a magnetic field sensor in the form of a magnetometer 14. Magnetometer 14 is installed on a structural element of bridge 100. Specifically, FIG. 1 schematically depicts magnetometer 14 installed on a roadway (or railway) support girder 102 of bridge 100. This particular application of the system is described for illustrative purposes only; the system can be used to measure the deflection of structural elements other than girder 102.

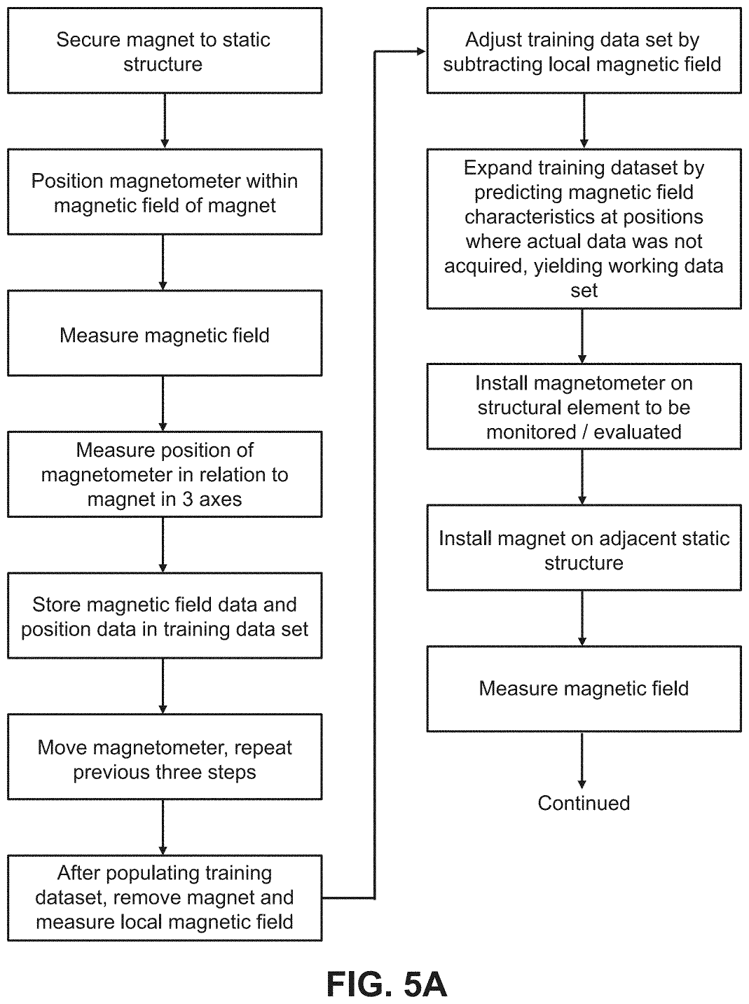

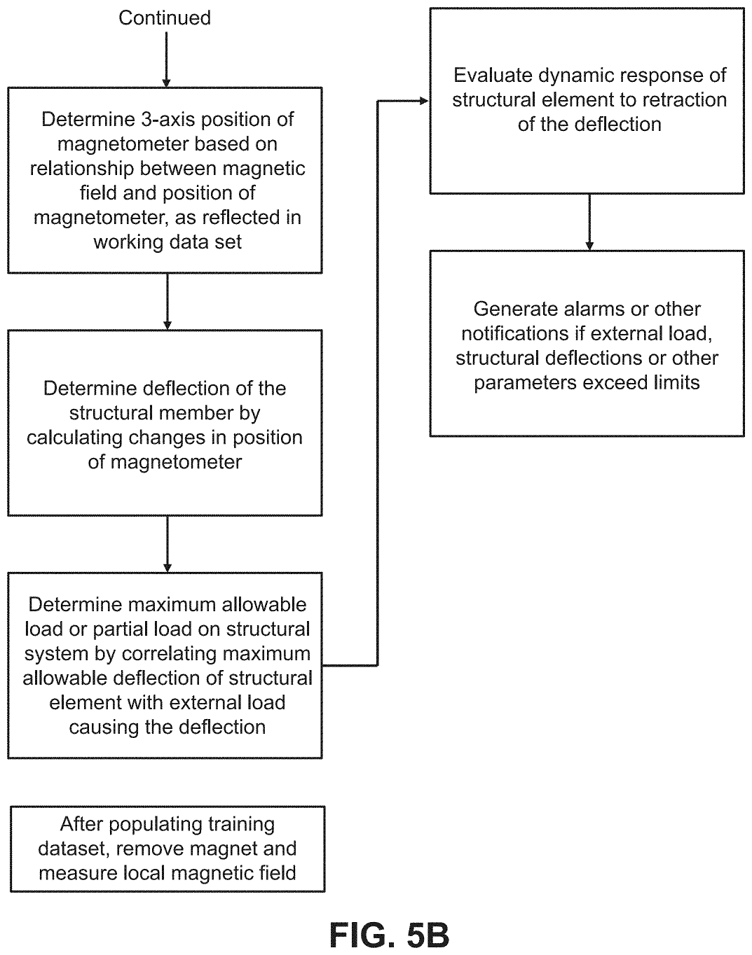

FIGS. 5A and 5B are flowcharts depicting use of the system to conduct structural health monitoring of bridge 100 or some other structural system.

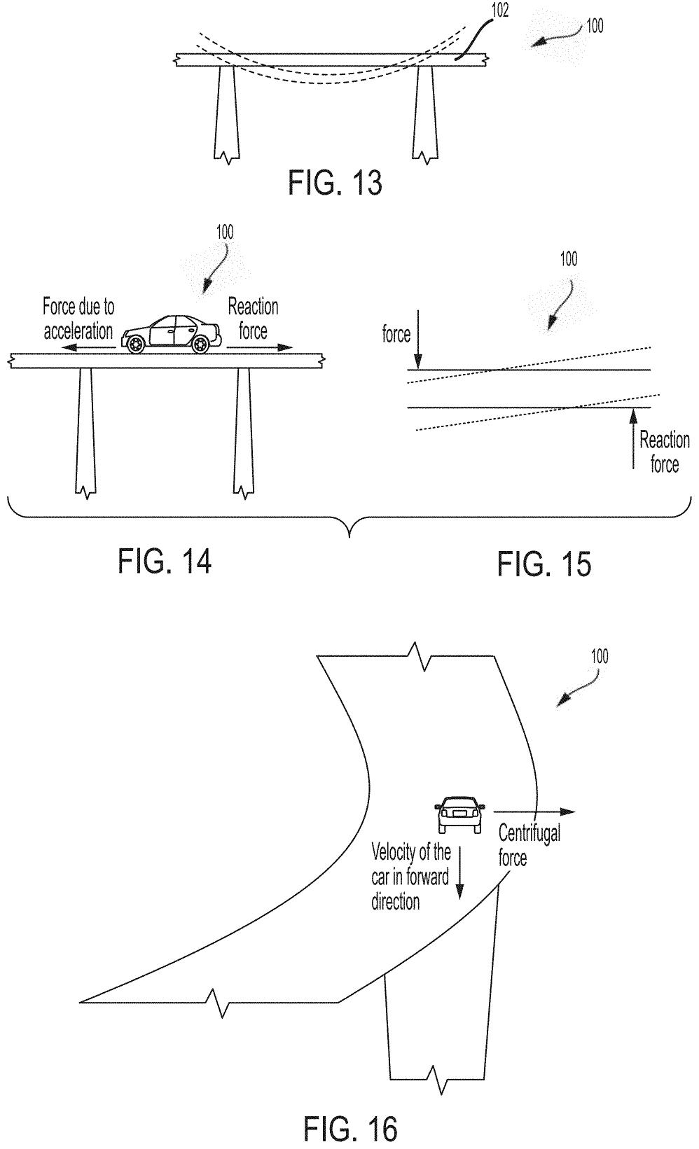

As can be seen in FIG. 1, magnetometer 14 is installed on the underside of girder 102, desirably closed to or even at the approximate horizontal mid-point of girder 102. Magnetometer 14 is positioned beneath girder 102 to avoid interfering with traffic on the roadway of bridge 100. The mid-span of girder 102 is the most heavily loaded portion of girder 102. FIG. 13 shows how girder 102 experiences maximum deflection at its horizontal mid-point in response to vehicular traffic on road deck 110. Thus, a girder at its horizontal mid-point, commonly a referred to as “mid-span,” is particularly vulnerable to cracking, deformation, and other damage, making it important to monitor the condition of girder 102 at that location.

Magnetometer 14 is secured to girder 102, so that magnetometer 14 undergoes the same deflection as girder 102 when girder 102 deflects under loading induced by vehicular traffic. Magnet 12 is mounted on a stationary structure, i.e. on a structure that does not move substantially in relation to the ground as the girder 102 deflects. For example, as shown in FIG. 2 magnet 12 can be secured to a “dummy girder” 112 positioned beneath girder 102 and anchored to the ground. Dummy girder 112 is configured so that magnetometer 14 is positioned within the three-dimensional magnetic field of magnet 12, but does not contact girder 102 or any other portion of bridge 100. Thus, when girder 102 deflects, relative movement between magnetometer 14 and magnet 12 substantially matches relative movement of the mid-span of girder 102 with respect to the earth.

The magnetic field produced by magnet 12 acts as a fixed reference frame against which three-dimensional deflection of girder 102 in relation to the ground or another structure can be quantified. In particular, the relative movement between magnet 12 and magnetometer 14 affects the characteristics of the magnetic field to which magnetometer 14 is subjected. In practice of the invention the relationship between the characteristics of the magnetic field as measured by magnetometer 14, and the position of magnetometer 14 in relation to magnet 12 are predetermined, so that that the position of magnetometer 14 in relation to magnet 12 at any time can be determined based on the characteristics of the magnetic field as measured by magnetometer 12. Thus, because magnetometer 14 is secured to, and deflects along with the mid-span portion of girder 102, and magnet 12 remains stationary in relation to the ground, namely the earth, as girder 102 deflects, three-dimensional deflection of the mid-span of the girder 102 in relation to the ground can be quantified in real-time based on characteristics of the magnetic field sensed by magnetometer 14.

Magnet 12 is a permanent magnet. Magnet 12 can be an electromagnet in alternative embodiments. Magnet 12 is preferably donut shaped and is preferably cast iron. However, magnet 12 can be formed from other materials, such as nickel, cobalt, and various alloys of these materials, which alloys may also include rare earth elements such as neodymium. Magnet 12 can have other shapes in alternative embodiments.

Magnetometer 14 is preferably a wireless tri-axial or three-axis magnetometer capable of measuring, in three orthogonal directions, the strength of the magnetic field to which it is subjected. Magnetometer 14 can be, for example, a Hall effect sensor, a magneto-diode, a magneto-transistor, and AMR magnetometer, a GMR magnetometer, a magnetic tunnel junction magnetometer, a magneto-optical sensor, a Lorentz force based MEMS sensor, an electron tunneling based MEMS sensor, a MEMS compass, a nuclear precision magnetic field sensor, an optically pumped magnetic field sensor, a fluxgate magnetometer, a search coil magnetic field sensor, or a SQUID magnetometer.

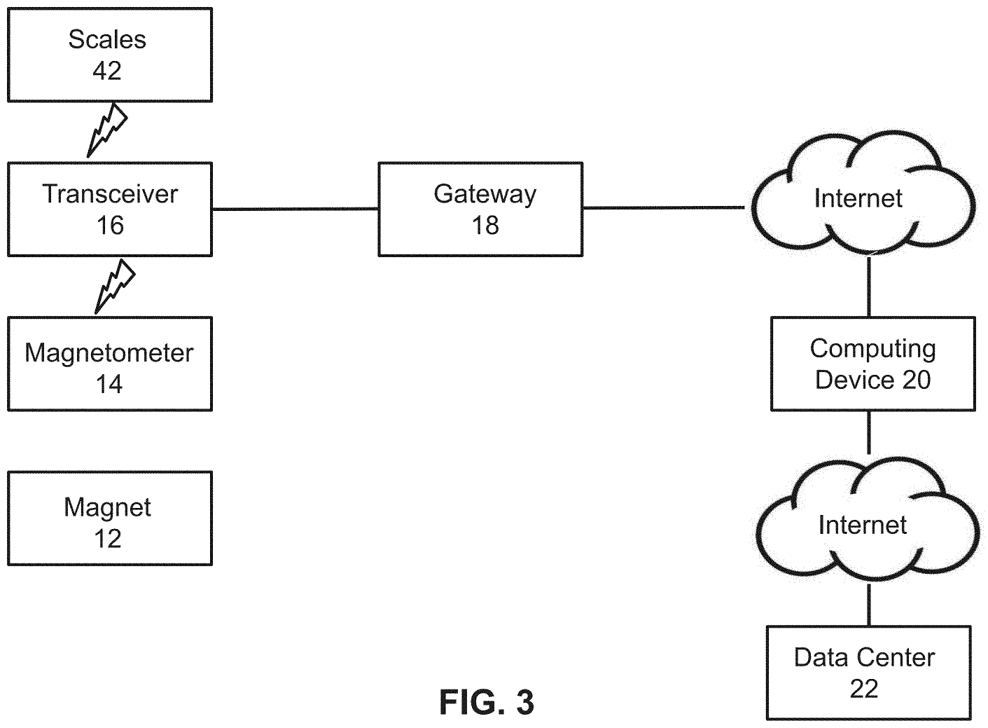

The magnetometer 14 is desirably configured to communicate on a wireless basis with a transceiver 16, depicted schematically in FIG. 3. Transceiver 16 is located at or near bridge 100, so that magnetometer 14 and transceiver 16 can communicate using a suitable short-range communication standard. For example, magnetometer 14 and transceiver 16 can communicate via WiFi, 2G, 3G, 4G, 5G, GPRS, EDGE, Bluetooth, ZigBee, Piconet of BLE, Zwave, or a combination of any of these; other communications protocols, including hard wire connections, can also be used.

As also depicted schematically in FIG. 3, system 10 desirably includes a gateway 18 and a computing device 20. Gateway 18 is desirably co-located with transceiver 16, and is communicatively coupled to transceiver 16. Gateway 18 desirably provides access to a wireless communication network such as the internet, and communicates with computing device 20 over such network. Gateway 18 can access the network wirelessly such as via a suitable cellular network or via a wired connection and can use any of the protocols identified above.

Gateway 18 can be configured to convert the output of transceiver 16 into a protocol, such as MQTT (MQ Telemetry Transport), suitable for facilitating the efficient transmission of data over the internet. In the alternative gateway 18 can transmit the data using other protocols.

Computing device 20 can be, for example, a personal computer, a server, a microcontroller, a smart phone, etc. Computing device 20 is configured to determine the three-dimensional deflection of girder 102 on a real-time basis. This determination is based on the output of magnetometer 14, the pre-determined relationship between the characteristics of the magnetic field of magnet 12 as measured by magnetometer 14, and the position of magnetometer 14 in relation to magnet 12.

Computing device 20 can optionally be configured to calculate maximum allowable vehicle weight for bridge 100 based on measured deflection of girder 102 or other structural element(s) of bridge 100. Computing device 20 can be configured to generate audible, visual, and/or electronic alarms and other types of notifications upon detecting the presence of an overweight vehicle(s); and/or when the measured deflection of girder 102 or other structural elements of bridge 100 are outside acceptable ranges. The notifications can be sent, for example, to the organization responsible for the operation or maintenance of bridge 100, via the internet or other suitable means.

In accordance with conventional edge computing paradigms, computing device 20 can be located close enough to bridge 100 to facilitate expedient routing of data between magnetometer 14 and computing device 20. Computing device 20 can be communicatively coupled to the cloud, i.e. to a remotely-located data center 22 having one or more servers or mainframe computers with greater data processing and data storage capabilities than computing device 20 alone. Computing device 20 and data center 22 preferably communicate via the internet or other suitable means. Long-term data storage can be performed at data center 22. Also, more complex and non-time-sensitive data analyses, such as trending and statistical analyses of the data, maintenance scheduling, maintenance tracking, generating maintenance notifications, etc., are desirably performed at data center 22.

Transceiver 16, gateway 18, and computing device 20 are most desirably configured to transmit and process data from more than one magnetometer 14, i.e. from additional magnetometers 14 positioned at other locations on bridge 100. Also, data center 22 can be configured to receive, process, and store data from structures in addition to bridge 100.

The specific network architecture described herein is disclosed for illustrative purposes only; other applications can incorporate different types of network architectures. For example, the processing and storage of the data generated by magnetometer 14 can be performed entirely by computing device 20, or entirely at data center 22 in alternative embodiments.

Magnetometer 14, transceiver 16, and gateway 18 are preferably powered by 120-volt alternating current provided by an electrical system associated with bridge 100. Alternatively, these components can be powered by a battery, and/or by an energy harvester such as a solar-panel array, a wind turbine, etc.

FIG. 2 depicts another application of the invention to measure deflection of road deck 110 in relation to concrete pier 108 of bridge 100. As discussed above, pier 108 is securely anchored to the ground and, along with other piers 108 located below road deck 110, supports the weight of road deck 110.

Road deck 110 and pier 108 may be separated by a bearing 114 such as that illustrated in FIG. 1. A bearing such as 114 when present, acts as the interface between road deck 110 and pier 108, and provides a resting surface between deck 110 and pier 108. Bearings such as 114 shown in FIG. 1, when present in the construction illustrated in FIG. 2, allow controlled, limited movement of road deck 110 relative to pier 108, thereby eliminating the potential for excessive structural loading that otherwise could result from a rigid connection between road deck 110 and pier 108. Thus, proper functioning of a bearing such as 114 can be critical to the structural integrity of roadway 110 and pier 108, making it important to monitor the condition of bearing 114 and the adjoining structure of bridge 100.

In another exemplary application not illustrated in FIG. 2, magnetometer 14 is securely mounted on the underside of road deck 110, directly above pier 108, so that magnetometer 14 deflects in unison with the adjacent, adjoining portion of road deck 110. Magnet 12 is securely mounted on a upper surface of pier 108, directly below magnetometer 14, so that magnetometer 14 is positioned within the magnetic field of magnet 12. The magnetic field of magnet 12 thus acts as a fixed reference frame against which the three-dimensional deflection of the portion of road deck 110 adjacent to bearing 114 can be quantified, in the manner described above in relation to girder 112.

Computing device 20 and/or the data center 22 are desirably configured to recognize specific characteristics and trends in the local deflection of road deck 110 in relation to pier 108 as an indication that a bearing such as 114 is not functioning properly, i.e. as an indication that a bearing such as 114 is not facilitating proper movement of road deck 110 in relation to pier 108. Computing device 20 and/or data center 22 are desirably further configured to generate an alarm or other type of audible, visible or electronic notification, and to schedule an inspection or maintenance event upon detecting a potential issue with the functioning of bearing 114. The notifications are desirably sent, for example, to the organization responsible for the operation and maintenance of the bridge 100 via the internet or other suitable communication means.

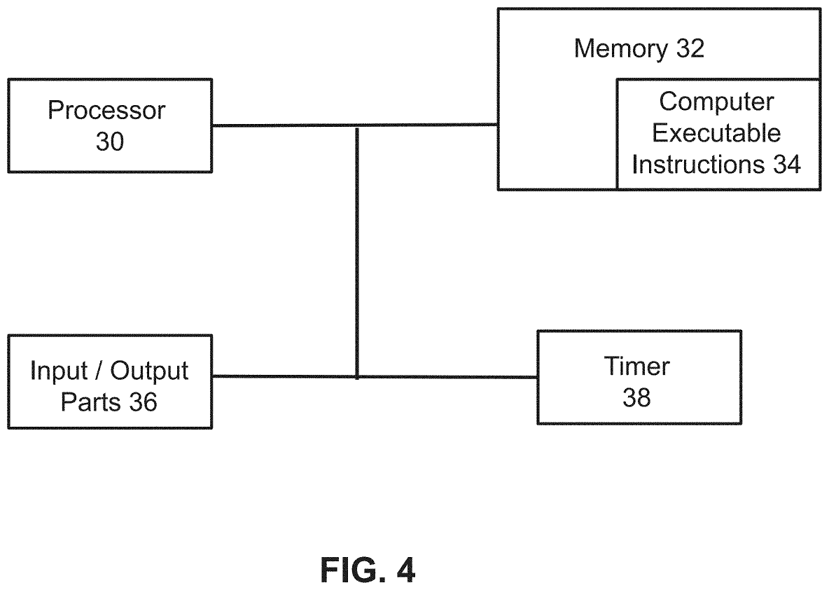

As depicted schematically in FIG. 4, computing device 20 preferably includes a processor 30 such as a microprocessor, a memory 32 communicatively coupled to microprocessor 30, and computer executable instructions 34 stored in memory 32. Computer executable instructions 34, when executed by processor 30, cause processor 30 to perform the logical operations required in the course of automated practice of the invention. Computing device 20 also desirably includes input/output ports 36, a timer 38, and a bus for facilitating internal communications within computing device 20. Computing device 20 can also include additional components, and can have configurations other than the configuration disclosed herein.

The above-described applications of detecting and measuring structural deflections are presented for illustrative purposes only. Such systems can be used to quantify the deflection of other structural elements of bridge 100, such as girder joints and concrete joints, and are not limited to these.

Computing device 20 is desirably configured to determine useful engineering and structural parameters other than the deflection of structural members and the loading of a bridge roadway. For example, computing device 20 is most desirably configured to determine dynamic response of a structural member to removal of a physical load from the member. This information is used to assess integrity of structural members such as girder 102.

The selected position of magnetometer 14 in three-dimensional space is based on the characteristics, i.e. magnitude and direction, of the magnetic field of magnet 12 as measured by magnetometer 14, and a pre-determined relationship between the characteristics of the magnetic field and the location of magnetometer 14 in relation to magnet 12. The description of how the relationship between the magnetic field of magnet 12 and the position of magnetometer 14 in two-dimensional space is established is presented below, with a description of how the relationship may be established in three-dimensional space following the two dimensional space description.

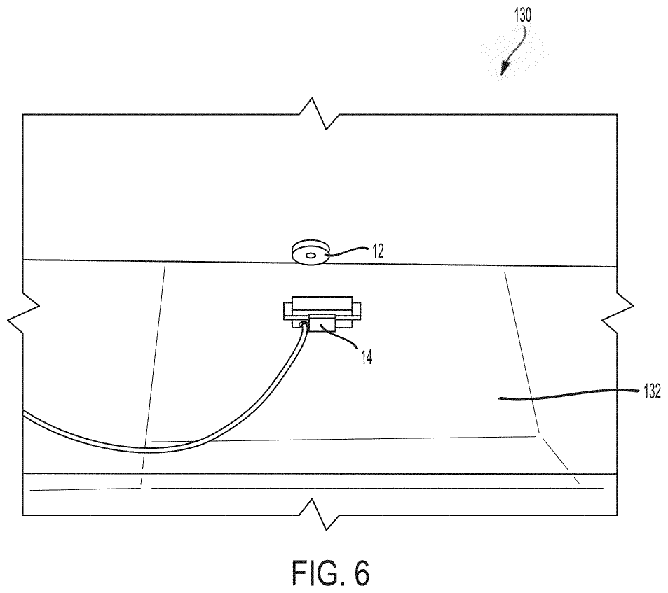

FIG. 6 depicts a system 130 for obtaining the two-axis deflection measurements in a laboratory setting. System 130 includes a magnet, such as magnet 12, and a magnetometer, such as magnetometer 14. Magnet 12 is kept at a fixed reference position on a support 132 of system 130. The vertical axis of magnet 12 is designated as the “x” axis for the purposes of this disclosure. System 130 also includes a computing device, such as computing device 20 shown in FIG. 3, communicatively coupled to magnetometer 14.

Referring further to FIG. 6, required two-axis measurements are acquired by moving magnetometer 14 into different positions on the horizontal “x-y” plane in relation to magnet 12, and recording the response of magnetometer 14 at each position. The magnetic field generated by magnet 12 at any position is designated “M_{R},” and its components along the x, y, and z axes are designated “M_{X},” M_{Y}, “and M_{Z},” respectively. Because any changes in Mₓ are substantially similar those occurring in M_{R}, the x axis is considered the axis of symmetry of magnet 12 for the purposes of this analysis.

Data relating to the magnetic field M_{R} and its components M_{X}, M_{Y}, and M_{Z} is harvested by the tri-axial magnetometer 14 as it is positioned at different locations in the x-y plane. This data is used to plot the magnetic field vector

$${\to }_{{M}_{R}}$$

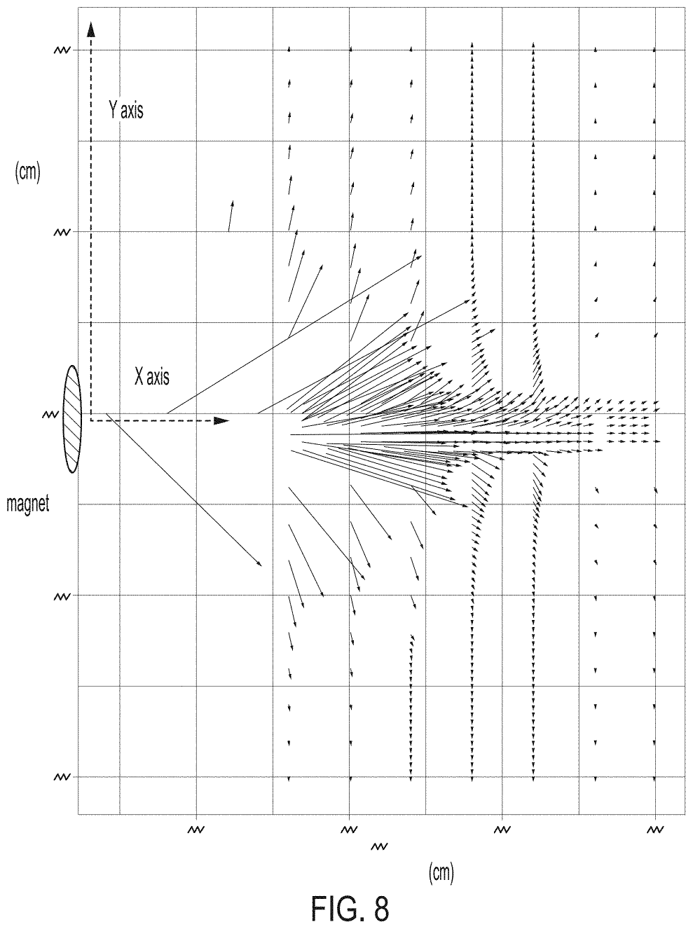

in the x-y plane. FIG. 8 shows the magnetic field M_{R} and its relative strength at different locations in the x-y plane and also the components M_{X} and M_{Y} at different locations in the x-y plane. As can be seen from FIG. 8, the characteristics of the magnetic field vary in the x-y plane in a non-random manner. Fitting a mathematical equation to this data is extremely difficult due to the complex manner in which the magnetic field vector M_{R} varies.

Similarly to the two dimensional situation, for three-axis measurements of the magnetic field,

Mₓ=f(x,y,z)

M_{y}=f(x,y,z)

M_{y}=f(x,y,z) (Equation (1))

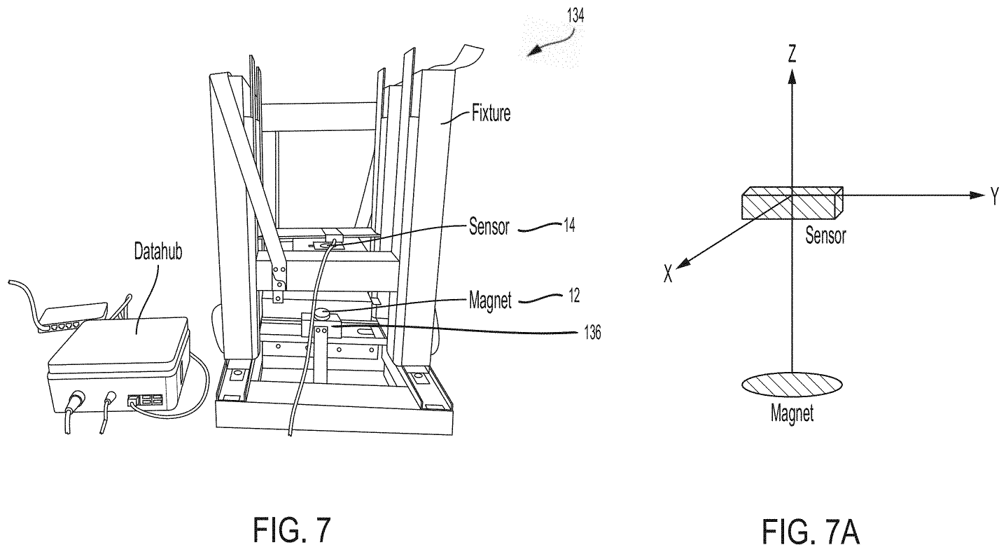

The illustrated donut shape of magnet 12 in FIG. 6 facilitates substantial congruence of the “z” and “M_{Z}” directional axes as illustrated in FIG. 7A, for the three dimensional case.

When the values of Mₓ, M_{y} and M_{z} are measured by magnetometer 14 at a position in three-dimensional space, solving the above three equations provides the coordinates of that position. This is only possible, however, when the functions are known. As with the two-dimensional mapping of the magnetic field illustrated in FIG. 8, fitting equations to these “three-dimensional” functions is extremely difficult due to the complex manner in which the magnetic field vector varies in three-dimensional space.

The inventive approach, instead of fitting equations to the underlying magnetic-field data, is to learn the above functions from empirical data using machine learning techniques. From the Equation 1 grouping above, it is known that the magnetic field components (M) are functions of x, y, and z, namely,

M→f(x,y,z)

In the inventive technique, the above functions are learned through reverse mapping, namely,

Q′: x→f′(Mₓ,M_{y},M_{z})

Q″: y→f″(Mₓ,M_{y},M_{z})

Q′″: z→f′″(Mₓ,M_{y},M_{z}) (Equation (2))

The invention uses an empirically-determined baseline “training” dataset to learn these functions.

FIG. 7 depicts a system 134 for obtaining the training dataset, and for validating position measurements acquired through the use of the training dataset. System 134 includes a magnet, such as magnet 12, and a sensor in the form of a magnetometer, such as magnetometer 14. Magnet 12 is kept at a fixed reference position on a support 136 of system 134. The vertical axis of magnet 12 is designated the “z” axis in this configuration. As noted above, FIG. 7A depicts the three axis coordinate system centered at magnetometer 14 with magnet 12 located on the negative z axis at a “zero” x and y axes location. System 134 also includes a computing device, such as computing device 20, illustrated schematically in FIG. 3, communicatively coupled to magnetometer 14. The x, y, and z axes are not depicted in FIG. 7, to enhance drawing clarity.

Three-axis deflection measurements are acquired by moving magnetometer 14 among different positions in three-dimensional “x-y-z” space in relation to magnet 12, recording the response of magnetometer 14 at each position, and measuring the actual physical position of magnetometer 14 in relation to magnet 12, in each of the three orthogonal x, y, and z directions, at each position.

After these magnetic-field readings are acquired with magnet 12 in place, magnet 12 is removed from support 136, and additional readings by magnetometer 14 are harvested. These readings, obtained without the influence of magnet 12, represent the characteristics of the earth's magnetic field in x, y, z coordinates as measured by magnetometer 14.

The magnitude readings of the earth's magnetic field in x, y, z coordinates, as measured by magnetometer 14, are subtracted from the acquired readings and are maintained in a training dataset, so that these training dataset readings reflect only the x, y, z components of the magnetic field generated by magnet 12 and measured by magnetometer 14.

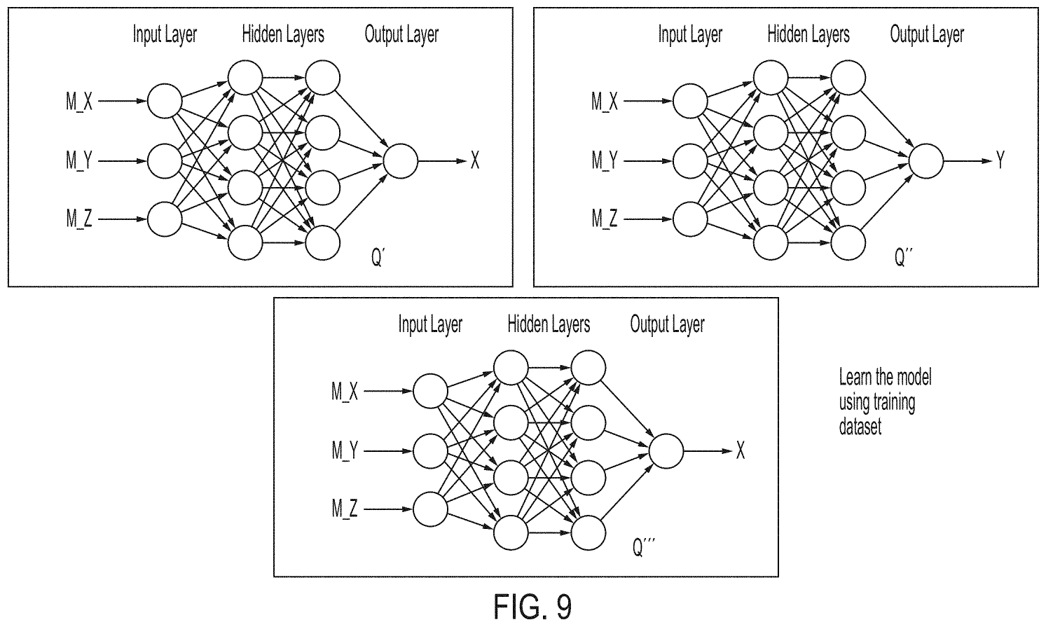

In one of its aspects the invention uses neural networking to map the magnetic field components to positions in three-dimensional space at which actual data was perhaps not acquired, based on the acquired data residing in the training dataset, as shown schematically in FIG. 9. The resulting dataset, referred to hereinafter as a “working dataset,” is a comprehensive representation of the relationship between the magnetic field generated by magnet 12 and the position of magnetometer 14 in three-dimensional space within the magnetic field of magnet 12. The working dataset is then used to determine position of magnetometer 14, in three-dimensional space, in relation to magnet 12, based on characteristics of the magnetic field as measured by magnetometer 14.

In one practice of the invention, magnet 12 and magnetometer 14 are subsequently installed on bridge 100 or some other structure as described above. The working dataset is downloaded into the memory 32 of computing device 20 or some other computing device, and is used to calculate deflection of the structural member on which magnetometer 14 is mounted. Computing device 20 is desirably positioned close to magnetometer 14 to minimize and essentially eliminate any time lag between the time magnetometer 14 takes a reading and the time computing device 20 computes deflection based on that reading.

Because the working dataset reflects the relationship between the characteristics, namely the three dimensional vectors, of the magnetic field generated by magnet 12 measured by magnetometer 14 and the three dimensional vector position of magnetometer 14 in relation to stationary magnet 12 in three-dimensional space, the “deflection” position of magnetometer 14 and the adjacent portion of the structural member that has been deflected, is determined by computing device 20 based on output of magnetometer 14.

In a preferred practice of the invention, the working dataset stored in memory 32 provides a look-up table. Processor 30, executing instructions 34, looks up the particular three-axis position value contained in the working dataset corresponding to the particular set of magnetic-field characteristics, namely the x, y, z, magnetic field strength vector values, measured by magnetometer 14. These position values represent the three-dimensional position of magnetometer 14, and the adjacent structure to which magnetometer 14 is secured, in relation magnet 12 at the time that particular set of characteristics, namely x, y, z magnetic field strength vector values, was acquired.

Computing device 20 is programmed and calculates changes in the position of magnetometer 14 on a real-time basis, and recognizes such changes as deflection(s) in the structure to which magnetometer 14 is secured. The system thereby monitors the dynamic response of the bridge structure to changing load conditions.

Computing device 20 is most desirably programmed to recognize when deflection of the structural member exceeds a predetermined threshold, and to generate alarms and other types of notifications upon such an occurrence. The deflection information is also desirably used for trending purposes, statistical analyses, maintenance scheduling and the like. Computing device 20 desirably caches the as-measured magnetic field data and the calculated deflection data in its memory, and transmits the data to data center 22 either at later time or in real time as the data is acquired.

If the original magnetometer 14 is replaced with a different magnetometer 14R on bridge 100, the replacement magnetometer 14R must be calibrated and is desirably calibrated in situ as follows. After replacement magnetometer 14R has been installed, position of the replacement magnetometer 14R in relation to magnet 12 is determined though physical measurements. Next, output of replacement magnetometer 14R is sampled one or more times with the structural element on which replacement magnetometer 14R is mounted being under a no-load condition. The acquired readings are averaged, yielding the characteristics of the magnetic field M^{S} at that location. Next, the characteristics of the magnetic field stored in the working dataset and corresponding to the position of replacement magnetometer 14R are looked up. These characteristics are denoted as “M^{S1}.” A calibration factor “c” then is determined as follows:

c=M^{S}−M^{S1} (3)

Once the calibration factor c has been determined, it is applied to data in the original working dataset corresponding to locations at and around the location of replacement magnetometer 14R, yielding a modified working dataset suitable for use with replacement magnetometer 14R. The system 10 is now configured to determine location of replacement magnetometer 14R in relation to magnet 12, and deflection of the structural member on which replacement magnetometer 14R is mounted, in the manner discussed above in connection with the original magnetometer 14.

The calibration process for replacement magnetometer 14R is desirably performed by computing device 20 on an automated basis. Calibrating replacement magnetometer 14R in situ based on the data contained in the original working dataset removes the earth's magnetic field, and any magnetic fields originating proximally or from other components of bridge 100, from the magnetic-field data obtained from replacement magnetometer 14R.

In the course of calibration of the magnetometer, multiple values of the magnetometer data, taken from multiple readings by the magnetometer, may be used in a feedback loop to enrich the dataset for calibration purposes. As more and more readings are taken by the magnetometer, those readings are provided to suitable data handling algorithms to provide the additional magnetometer readings as data in a feedback fashion, resulting in greater accuracy in the training data set around the position where the sensor has been installed. The more data points provided by magnetometer readings for calibration, the better and more accurate the readings of the magnetometer after calibration, when installed on a structure of interest.

The invention desirably also desirably includes one or more devices to determine dynamic loading of road deck 110 or other roadway structure supported by the structural element(s) whose deflection(s) is/are being measured. These devices can be, for example, one or more weigh-in-motion scales 42, such as those depicted schematically in FIG. 3, that weigh a vehicle traveling on a roadway while the vehicle is in motion, using a combination of load cells, and inductive loops that detect the presence of the vehicle.

Still referring to FIG. 3, weigh-in-motion scales 42 are communicatively coupled to computing device 20 by way of transceiver 16 and gateway 20. Scales 42 provide computing device 20 with a real-time indication of the dynamic load on road deck 110 of a bridge such as bridge 100 depicted schematically in FIGS. 1, 2, and 14 through 16. The computing device 20 is programmed to correlate deflection of the structural element on which magnetometer 14 is mounted with a dynamic load applied to road deck 110. The maximum permissible deflection of the structural element is correlated with dynamic loading that results in the maximum permissible amount of deflection, to determine the maximum allowable amount of dynamic loading of the structural element. Once the maximum allowable dynamic loading is determined, the operator of bridge 100 can assign a maximum allowable vehicle weight for bridge 100.

Due to the highly desirable relatively close proximity of computing device 20 to magnetometer 14, network time lag is minimal, allowing the acquired magnetic-field data to be processed on a real-time, or near real-time basis. Thus, the invention can provide the operating authority of bridge 100 with virtually instantaneous notifications of detected anomalies. Such anomalies can include, for example, an overweight vehicle on bridge 100, possible structural issues as reflected by excessive deflection of a particular structural member, or an anomalous pattern in the dynamic response of structural member retraction after deflection. The condition monitoring provided by the invention as implemented on an ongoing basis is significantly lower in cost than condition monitoring provided by other methods such as laser scanning.

The disclosed inventive methodology for determining three-dimensional deflection of structural elements has been validated in a laboratory setting. A training dataset was generated in the above-described manner using system 134 illustrated in FIG. 7. In generating the training data set, a replacement magnetometer 14R, i.e. a magnetometer other than magnetometer 14 used to generate the original training dataset, was used. Magnetometer 14R was moved in relation to magnet 12 in three-dimensional space, and magnetic-field readings were acquired at positions other than those at which the data for the original training dataset was acquired. A second training dataset was generated, based on the magnetic field readings taken at these different positions. A second working dataset was generated based on the second training dataset, using neural-networking techniques disclosed above. The second working dataset was then used to determine position of magnetometer 14R, in three-dimensional space, in relation to magnet 12.

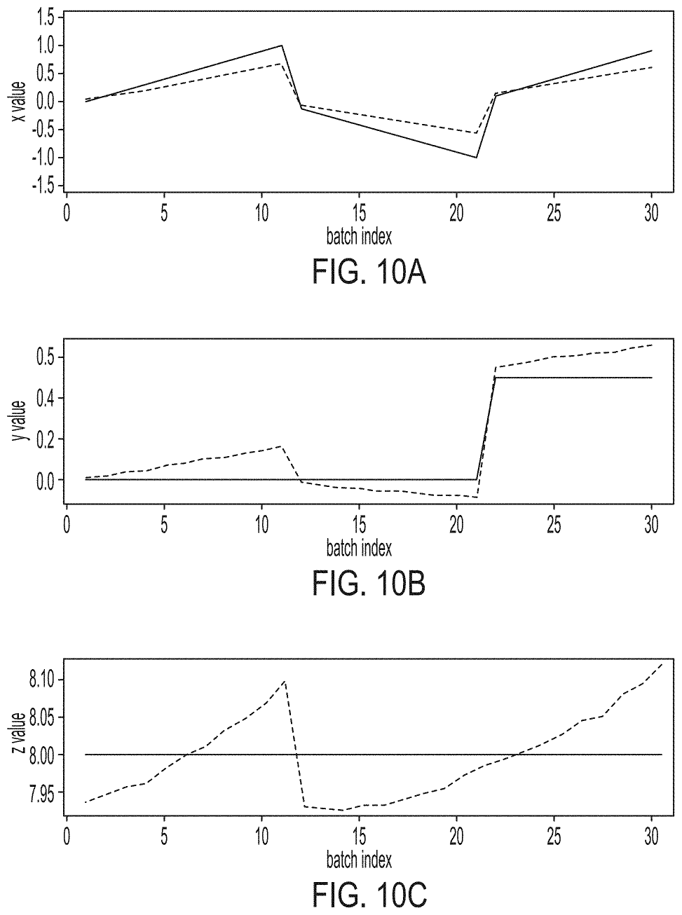

The x, y, and z-axis position values determined using the magnetic field measurements compared favorably with the position values determined using actual position measurements, i.e. actual measurements of the distances between magnetometer 14R and magnet 12 in the x, y, and z directions. FIG. 10A shows the predicted values, and the actual measured values of the x-axis position for a collection of readings taken a different positions, as indicated on the horizontal axis. The mean of squared error of these values is about 0.043, i.e. about 4% error. FIG. 10B shows the predicted and the actual values of the y-axis position. The mean of squared error for these values is about 0.008, i.e. about 0.8% error. Similarly, FIG. 10C shows the predicted and the actual values of the z-axis position. The mean of squared error for these values is about 0.003, i.e. about 0.3% error.

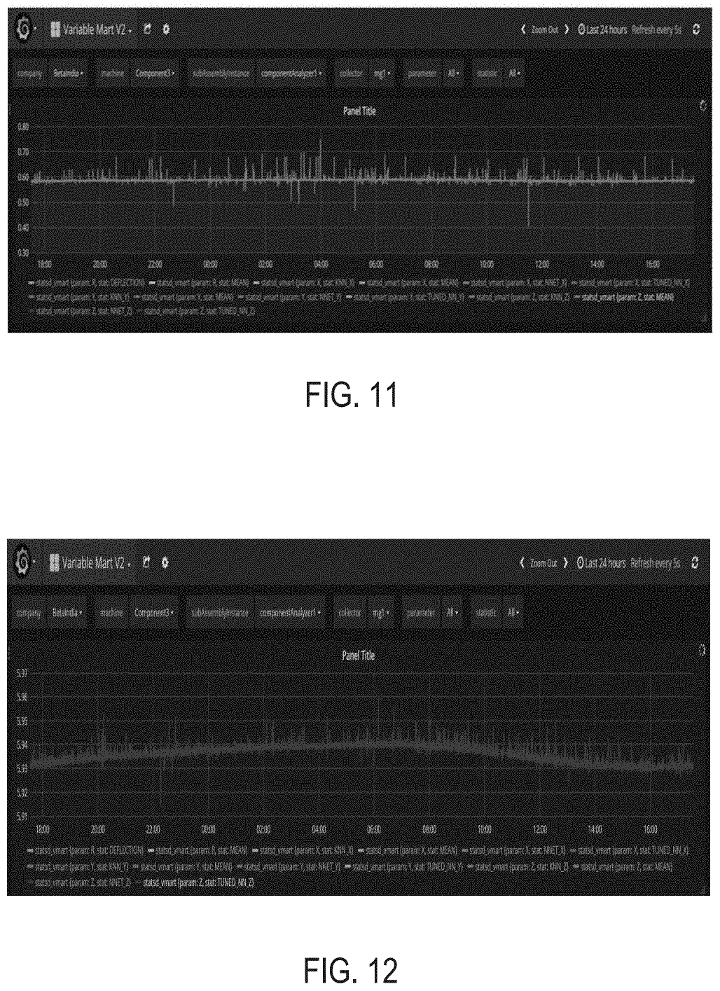

Further validation testing was performed by installing a system on an actual bridge, and acquiring measurements of the magnetic field of magnet 12 using magnetometer 14. FIG. 11 depicts the acquired magnetic field data, and FIG. 12 depicts the position, namely deflection data generated from the magnetic field data, both Figures showing time on the horizontal axis.

FIG. 11 presents a graphic picture of detected changes in a magnetic field in the “z” direction which were sensed by a magnetometer upon vehicles crossing over a bridge as a function of time. The spikes of the data in FIG. 11 extending downwardly from and below the mean data point of 0.58 are noise.

FIG. 12 presents a graphic picture over the course of a day of variations in deflection of a bridge girder, such as the one depicted schematically in FIGS. 1 and 13. The FIG. 12 data indicate that deflection is relatively minimal value at 1800 hours. FIG. 12 shows some smoothing of the deflection data, which is to be expected from natural damping of the bridge structure as numerous vehicles pass thereover.

The FIG. 11 data indicate that the number of changes in the magnetic field sensed by the magnetometer increase significantly after 1800 hours, reaching a peak at about 0400 hours, and then decrease slowly to what appears to be a reasonably steady state level at about 1600 to 1700 hours. The deflection presented in FIG. 12 clearly correspond in a gross fashion to the magnetic field change data presented in FIG. 11.

In another practice of the invention, load cells are mounted on bridges to determine cut-off or maximum values for dynamic loads that can be permitted for a bridge. When a heavy load, such as a heavily-loaded truck, traverses the bridge, the load cell or cells converts the impact force on the road bed created by the heavily-loaded truck into an electrical signal. Amplitude of the resulting electrical signal is a measure of the amount of the load. This “load” data is desirably combined with magnetometer-generated deflection data obtained in accordance with the invention, with structural analyses and strength of materials data to provide a clear picture of what is the maximum allowable load for the bridge to carry.

Although schematic implementations of present invention and some of its advantages are described in detail hereinabove, it should be understood that various changes, substitutions and alterations may be made to the apparatus and methods disclosed herein without departing from the spirit and scope of the invention as defined by the appended claims. The disclosed embodiments are therefore to be considered in all respects as being illustrative and not restrictive with the scope of the invention being indicated by the appended claims rather than by the foregoing description. All changes which come within the meaning and range of equivalency of the claims are therefore intended to be embraced therein. Moreover, the scope of this patent application is not intended to be limited to the particular implementations of apparatus and methods described in the specification, nor to any methods that may be described or inferentially understood by those skilled in the art to be present as described in this specification.

As disclosed above and from the foregoing description of exemplary embodiments of the invention, it will be readily apparent to those skilled in the art to which the invention pertains that the principles and particularly the compositions and methods disclosed herein can be used for applications other than those specifically mentioned. Further, as one of skill in the art will readily appreciate from the disclosure of the invention as set forth hereinabove, apparatus, methods, and steps presently existing or later developed, which perform substantially the same function or achieve substantially the same result as the corresponding embodiments described and disclosed hereinabove, may be utilized according to the description of the invention and the claims appended hereto. Accordingly, the appended claims are intended to include within their scope such apparatus, methods, and processes that provide the same result or which are, as a matter of law, embraced by the doctrine of the equivalents respecting the claims of this application.

As respecting the claims appended hereto, the term “comprising” means “including but not limited to”, whereas the term “consisting of” means “having only and no more”, and the term “consisting essentially of” means “having only and no more except for minor additions which would be known to one of skill in the art as possibly needed for operation of the invention.” The scope of the invention is, therefore, indicated by the appended claims rather than by the foregoing description and all changes which come within the range of equivalency of the claims are to be considered to be embraced within the scope of the claims. Additional objects, other advantages, and further novel features of the invention will become apparent from study of the appended claims as well as from study of the foregoing detailed discussion and description of the invention, as that study proceeds.

The following is claimed:

1. A system for monitoring a structural element, comprising:
a) a magnetometer capable of being mounted on the structural element;
b) a magnet capable of being mounted on a surface adjacent the structural element so that the magnetometer is positioned within a magnetic field of the magnet; and
c) a computing device capable of being communicatively coupled to the magnetometer;
wherein the magnetometer is configured to measure characteristics of the magnetic field of the magnet; and the computing device is configured to determine position of the magnetometer in relation to the magnet based on the measured characteristics of the magnetic field.

2. The system of claim 1 wherein the computing device is configured to determine a position of the magnetometer in relation to the magnet in three-dimensional space based on the measured characteristics of the magnetic field.

3. The system of claim 2 wherein the measured characteristics of the magnetic field include a magnitude of the magnetic field in three orthogonal directions.

4. The system of claim 1 further comprising a gateway communicatively coupled to the magnetometer and configured to transmit an output of the magnetometer to the computing device over the Internet.

5. The system of claim 1 wherein the computing device comprises a memory containing information regarding a relationship between the characteristics of the magnetic field and the position of the magnetometer in relation to the magnet.

6. The system of claim 1 wherein the computing device is further configured to determine a deflection of the structural member by calculating a difference between a position of the structural member in relation to the magnet at a first time, and a position of the structural member in relation to the magnet at a second time.

7. The system of claim 6 wherein the computing device is further configured to determine a dynamic response of a retraction of the deflection of the structural member.

8. The system of claim 6 wherein the computing device is further configured to determine deflection of the structural member by calculating:
a) a difference between a position of the structural member in relation to a first reference axis and the magnet at the first time, and a position of the structural member in relation to the first reference axis and the magnet at the second time;
b) a difference between a position of the structural member in relation to a second reference axis and the magnet at the first time, and a position of the structural member in relation to the second reference axis and the magnet at the second time; and
c) a difference between a position of the structural member in relation to a third reference axis and the magnet at the first time, and a position of the structural member in relation to the third reference axis and the magnet at the second time; the first, second and third reference axes being orthogonal.

9. The system of claim 6 wherein the computing device is further configured to continually monitor the position of the magnetometer in relation to the magnet.

10. The system of claim 6 wherein the computing device is further configured to generate a notification when the deflection of the structural member exceeds a predetermined value.

11. The system of claim 6 wherein: the structural element is part of a structure having a roadway; and the system further comprises a load measuring device configured to be communicatively coupled to the computing device, and to determine a load on the roadway.

12. The system of claim 11 wherein the computing device is further configured to determine a maximum load on the roadway by determining the load on the roadway when the deflection of the structural member reaches a predetermined maximum value.

13. The system of claim 1 wherein the computing device is a first computing device, and the system further comprises a second computing device configured to be communicatively coupled to the first computing device, and further configured to store data relating to the measured characteristics of the magnetic field and/or to perform additional processing operations on the data relating to the measured characteristics of the magnetic field.

14. The system of claim 1 wherein the surface adjacent the structural element is a surface that does not deflect substantially when the structural element is subjected to a load within the structural limitation of the structural element.

15. A method for monitoring a structural element, comprising:
a) mounting a magnetometer on the structural element;
b) mounting a magnet on a surface adjacent the structural element so that the magnetometer is positioned within a magnetic field of the magnet;
c) measuring characteristics of the magnetic field of the magnet; and
d) determining a position of the magnetometer in relation to the magnet based on the measured characteristics of the magnetic field.

16. The method of claim 15 wherein measuring characteristics of the magnetic field of the magnet comprises measuring characteristics of the magnetic field in three orthogonal directions.

17. The method of claim 15 wherein measuring characteristics of the magnetic field of the magnet comprises measuring a strength of the magnetic field.

18. The method of claim 15 wherein determining a position of the magnetometer in relation to the magnet based on the measured characteristics of the magnetic field comprises determining the position of the magnetometer in relation to the magnet based on a relationship between the characteristics of the magnetic field, and the position of the magnetometer in relation to the magnet.

19. The method of claim 15 wherein mounting a magnet on a surface adjacent the structural element so that the magnetometer is positioned within a magnetic field of the magnet comprises mounting the magnet on a surface that does not deflect substantially when the structural element is subjected to a load.

20. The method of claim 15 further comprising determining a deflection of the structural member when the structural member is subjected to a load by calculating a difference between a position of the magnetometer in relation to the magnet when the structural member is not subjected to the load, and a position of the magnetometer in relation to the magnet when the structural member is subjected to the load.

21. The method of claim 15 further comprising determining a deflection of the structural member by calculating a difference between a position of the structural member in relation to the magnet at a first time, and a position of the structural member in relation to the magnet at a second time.

22. The method of claim 21 further comprising determining a maximum load on a roadway supported at least in part by the structural member by measuring loads on the roadway and identifying the load on the roadway when the deflection of the structural member reaches a predetermined maximum value.

23. The method of claim 21 further comprising determining a dynamic response of a retraction of the deflection of the structural member.

24. The method of claim 21 wherein determining a deflection of the structural member further comprises:
a) calculating a difference between a position of the structural member in relation to a first reference axis and the magnet at the first time, and a position of the structural member in relation to the first reference axis and the magnet at the second time;
b) calculating a difference between a position of the structural member in relation to a second reference axis and the magnet at the first time, and a position of the structural member in relation to the second reference axis and the magnet at the second time; and
c) calculating a difference between a position of the structural member in relation to a third reference axis and the magnet at the first time, and a position of the structural member in relation to the third reference axis and the magnet at the second time; the first, second and third reference axes being orthogonal.

25. The method of claim 21 further comprising generating a notification when the deflection of the structural member exceeds a predetermined value.

26. A method for measuring structural deflection, comprising:
a) positioning a wireless magnetometer on a the portion of a structure where deflection is to be measured;
b) fixedly positioning a magnet within wireless communication range of the magnetometer and sufficiently close to the structure portion of interest that the structure portion of interest is within the magnetic field of the magnet;
c) sensing a magnetic field vector with the magnetometer as the portion of the structure deflects;
d) dynamically providing the sensed magnetic field vector position to a edge cloud computing device as the portion of the structure deflects;
e) extracting as deflection information the position of the portion of the structure for which deflection is to be measured from the dynamically provided magnetic field vector position via an algorithm executed by the edge cloud computing device; and
f) transmitting the deflection information from the edge cloud computing device to a user.

27. The method of claim 26 wherein the structural deflection to be measured is vertical deflection and positioning the magnetometer and the magnet further comprises vertically aligning the magnetometer and the magnet.

28. The method of claim 27 further comprising positioning the magnet below the magnetometer.

29. A method for calibrating a wireless sensing magnetometer for use with a magnet for detecting structural deflection, consisting of:
a) moving a reference magnetometer throughout a preselected space to collect data of magnetic field strength of the magnet respecting a three axis coordinate system;
b) positioning the magnet such that the magnetic field thereof no longer occupies the preselected space;
c) moving the reference magnetometer through the preselected space to collect data of the earth's magnetic field respecting the three axis coordinate system;
d) subtracting the magnetic field data collected in step “c” from the magnetic field data collected in step “b” to produce a first training data set containing three position magnetic field components of the magnet measured by the reference magnetometer respecting the three axis coordinate system;
e) positioning the wireless sensing magnetometer at a selected position within the magnetic field of the magnet and measuring strength of the magnetic field thereat with the wireless sensing magnetometer;
f) using the wireless sensing magnetometer, measuring a second training data set magnetic field strength at the position corresponding to the selected position within the magnet magnetic field; and
g) subtracting the magnetic field strength sensed by the sensing magnetometer in the second training data set from magnetic field strength sensed by the reference magnetometer in the first training data set to determine a calibration of the wireless sensing magnetometer relative to the reference magnetometer.

30. A method for calibrating a wireless sensing magnetometer for use with a magnet for detecting structural deflection, comprising:
a) moving a reference wireless magnetometer throughout a preselected space to collect data of magnetic field strength of the magnet respecting a three axis coordinate system;
b) positioning the magnet such that the magnetic field thereof no longer occupies the preselected space;
c) moving the reference magnetometer through the preselected space to collect data of the earth's magnetic field respecting the three axis coordinate system;
d) subtracting the magnetic field data collected in step “c” from the magnetic field data collected in step “b” to produce a first training data set containing only magnetic field components of the magnet measured by the reference magnetometer respecting the three axis coordinate system;
e) positioning the wireless sensing magnetometer at a selected position within the magnetic field of the magnet and measuring strength of the magnetic field thereat with the wireless sensing magnetometer;
f) using the wireless sensing magnetometer, measuring a second training data set of magnetic field strength at the position corresponding to the selected position within the magnet magnetic field; and
g) subtracting the second training data set of magnetic field strength sensed by the sensing magnetometer in the training data set from the first training set of magnetic field strength sensed by the reference magnetometer to determine a calibration of the sensing magnetometer relative to the reference magnetometer.

31. A method for measuring structural deflection, consisting of:
a) positioning a wireless magnetometer on the portion of a structure where deflection is to be measured;
b) fixedly positioning a magnet within wireless communication range of the magnetometer and sufficiently close to the structure portion of interest that the structure portion of interest is within the magnetic field of the magnet;
c) sensing a magnetic field vector with the magnetometer as the portion of the structure deflects;
d) dynamically providing the sensed magnetic field vector position to a edge cloud computing device as the portion of the structure deflects;
e) extracting as deflection information the position of the portion of the structure for which deflection is to be measured from the dynamically provided magnetic field vector position via an algorithm executed by the edge cloud computing device; and
f) transmitting the deflection information from the edge cloud computing device to a user.

32. The method of claim 31 wherein the structural deflection to be measured is vertical deflection and positioning the magnetometer and the magnet further comprises vertically aligning the magnetometer and the magnet.

33. The method of claim 32 further comprising positioning the magnet below the magnetometer.

34. A method for measuring structural deflection consisting of:
a) providing a magnet having a magnetic field occupying a preselected space;
b) moving a magnetometer throughout the preselected space to collect data of magnetic field strength of the magnet respecting a three axis coordinate system;
c) positioning the magnet such that the magnetic field no longer fills the preselected space;
d) moving the magnetometer through the preselected space to collect data of the earth magnetic field respecting the three axis coordinate system;
e) subtracting the magnetic field data collected in step “d” from the magnet field data collected in step “b” to produce a data set containing only the magnetic field components of the magnet measured by the magnetometer respecting the three axis coordinate system; and
f) for each of the three directions defined by the coordinate system, applying the magnetic field components from step “e” to neural networks to produce a machine learning for determining the three position coordinates of the magnetometer relative to the magnet.

35. The method of claim 18, further comprising determining the relationship between the characteristics of the magnetic field, and the position of the magnetometer in relation to the magnet by:
a) placing the magnetometer in a first position in relation to the magnet;
b) measuring the first position of the magnetometer in relation to the magnet;
c) determining the response of the magnetometer to the magnetic field at the first position;
d) correlating the measured first position of the magnetometer to the response of the magnetometer to the magnetic field at the first position;
e) placing the magnetometer in a second position in relation to the magnet;
f) measuring the second position of the magnetometer in relation to the magnet;
g) determining the response of the magnetometer to the magnetic field at the second position; and
h) correlating the measured second position of the magnetometer to the response of the magnetometer to the magnetic field at the second position.

36. The method of claim 35, wherein determining the relationship between the characteristics of the magnetic field, and the position of the magnetometer in relation to the magnet further comprises using neural networking techniques to predict a response of the magnetometer to the magnetic field at a third position in relation to the magnet, based on the responses of the magnetometer to the magnetic field at the first and second positions.

37. The method of claim 18, wherein the magnetometer is a first magnetometer, and the method further comprises:
a) removing the first magnetometer from the structural element;
b) mounting a second magnetometer on the structural element;
c) measuring characteristics of the magnetic field of the magnet using the second magnetometer;
d) measuring the position of the second magnetometer in relation to the magnet;
e) determining, from the relationship between the characteristics of the magnetic field and the position of the first magnetometer in relation to the magnet, a response of the first magnetometer to the magnetic field of the magnet at the measured position of the second magnetometer;
f) determining a difference between the response of the first magnetometer to the magnetic field of the magnet at the measured position of the second magnetometer, and the response of the second magnetometer to the magnetic field of the magnet at the measured position of the second magnetometer;
g) based on the difference, adjusting the relationship between the characteristics of the magnetic field and the position of the first magnetometer in relation to the magnet; and
h) determining the position of the second magnetometer in relation to the magnet based on the adjusted relationship between the characteristics of the magnetic field, and the position of the first magnetometer in relation to the magnet.
